(19) United States
(12) Patent Application Publication
(10) Pub. No.: US 2026/0324256 A1
(43) Pub. Date: Oct. 15, 2026

(54) DISPLAY DEVICE AND MOBILE TERMINAL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jun YANG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 19/100,133

(22) PCT Filed: Aug. 19, 2024
(86) PCT No.: PCT/CN2024/113122

§ 371 Date: Jan. 31, 2025

(30) Foreign Application Priority Data
Dec. 14, 2023 (CN) 202311734212.8

(51) Int. Cl. H10K 59/80; H10H 29/853; H10H 29/855

(52) U.S. Cl. CPC H10K 59/873; H10H 29/853; H10H 29/8552; H10K 59/8792

(57) ABSTRACT

A display device and a mobile terminal are provided. The display device includes a functional addition area and a display area. The functional addition area includes a functional area and a first transition area located between the display area and the functional area. The display device includes a display panel and a cover plate disposed on the display panel. The cover plate includes a cover plate main body and a light-shielding layer. The cover plate main body has a first groove. The first groove is located in the first transition area and surrounds the functional area, and the light-shielding layer is filled in the first groove.

The present application claims the priority to Chinese Application No. 202311734212.8, filed on Dec. 14, 2023, the content of which is incorporated herein by reference in its entirety.

### TECHNICAL FIELD

The present application relates to a technical field of display, and in particular to display devices and mobile terminals.

### BACKGROUND

With the development of display technology, especially a development of full-screen technology, manufacturers currently have a variety of ways to increase a proportion of a screen. Among them, the most popular one is to open a hole in a display area of a display device and arrange an in-plane camera (i.e., under-screen camera technology).

Currently, an ink layer is usually disposed on a position of a cover plate relative to a non-display area of a display module, so as to beautify the appearance. While using adhesive glue to paste the cover plate and the ink layer, in the position of the cover plate relative to the non-display area of the display module, due to the ink layer, the ink layer has a certain thickness, which leads to the thickness of the cover plate at different positions in a light transmitting area is inconsistent, then an optical path difference of the light entering a camera hole at different positions in the light transmitting area is inconsistent, leading to an optical path distortion of an incident light entering the camera, which has a deteriorating effect on an imaging of the camera.

### SUMMARY

Embodiments of the present application provides a display device and a mobile terminal to alleviate deficiencies in related art.

In order to achieve above functions, solutions provided by the present application are as follows.

The embodiments of the application provide a display device, including functional addition area and a display area located in a periphery of the functional addition area, where the functional addition area includes a functional area and a first transition area located between the display area and the functional area. The display device includes:
a display panel; and
a cover plate, disposed on the display panel, where the cover plate includes a cover plate main body, the cover plate main body is provided with a first groove, and the first groove is located in the first transition area and surrounds the functional area;
where the cover plate further includes a light-shielding layer, and the light-shielding layer is filled in the first groove.

The embodiments of the application provide a mobile terminal, including a terminal main body and a display device, where the terminal main body is integrated with the display device, the display device includes a functional addition area and a display area located in a periphery of the functional addition area, and the functional addition area includes a functional area and a first transition area located between the display area and the functional area. The display device includes:
a display panel; and
a cover plate, disposed on the display panel, where the cover plate includes a cover plate main body, the cover plate main body is provided with a first groove, and the first groove is located in the first transition area and surrounds the functional area;
where the cover plate further includes a light-shielding layer, and the light-shielding layer is filled in the first groove.

### BRIEF DESCRIPTION OF THE DRAWINGS

In combined with the accompanying drawings, through the detailed description of the embodiments of the present application, the solutions of the present application and the beneficial effects will be obvious.

FIG. 1 is a structure diagram of a traditional display device with a under-screen camera;

FIG. 2 is a top view of a display device provided by embodiments of the present application;

FIG. 3 is a cross-section diagram of a first structure of the display device at A-A′ in FIG. 2;

FIG. 4 is a cross-section diagram of a cover plate provided by embodiments of the present application;

FIG. 5 is a structure diagram of a traditional packaging structure;

FIG. 6 is a cross-section top view of a first structure of the cover plate provided by embodiments of the present application; and

FIG. 7 is a cross-section diagram of a second structure of the display device at A-A′ in FIG. 2.

### DETAILED DESCRIPTION

The solutions in the embodiments of the present application will be clearly and completely described below with reference to the accompanying drawings. It should be understood that the described embodiments are merely a part of the embodiments of the present application, rather than all the embodiments. Based on the embodiments in the present application, all other embodiments obtained by a person skilled in the art without involving any inventive effort are within the scope of the present application.

Referring to FIG. 1, it is a structure diagram of a traditional display device with a under-screen camera.

In a display device 10 in the existing art, an ink layer 13 is usually disposed around a light transmitting area of a cover plate 11 relative to a display module 12, so as to beautify the appearance. While an adhesive 14 is used to attach the cover plate 11 and the ink layer 13, due to a certain thickness of the ink layer 13, the thickness of the cover plate 11 at different positions in the light transmitting area 100 is inconsistent, and an optical path difference of a light entering a camera hole 10A at different positions in the light transmitting area 100 is inconsistent, resulting in an optical path distortion of an incident light entering a camera 15, which has a deteriorating effect on an imaging of the camera 15. Based on this, the present application provides a display device and a mobile terminal, which may solve the above defect.

The embodiments of the present application provide a display device and a mobile terminal. The following are described in detail. It should be noted that the description order of the following embodiments is not a limitation on a preferred order of embodiments.

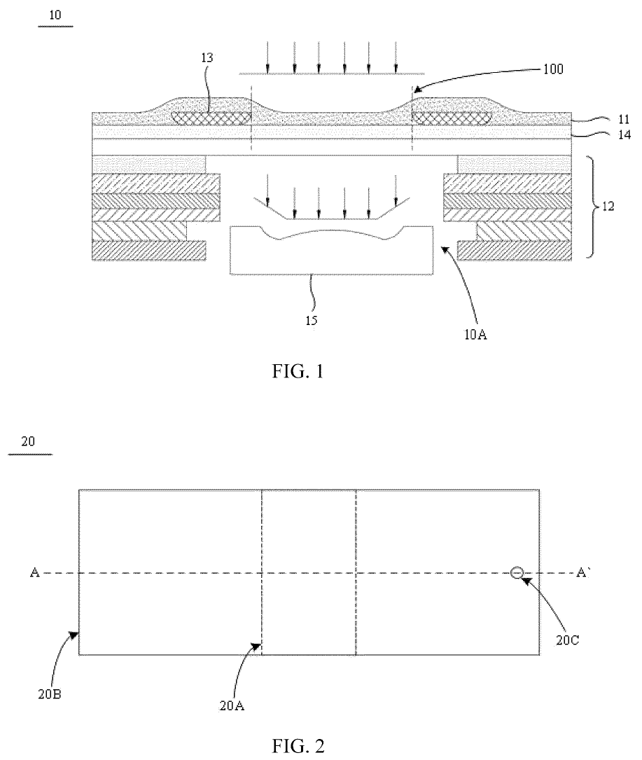

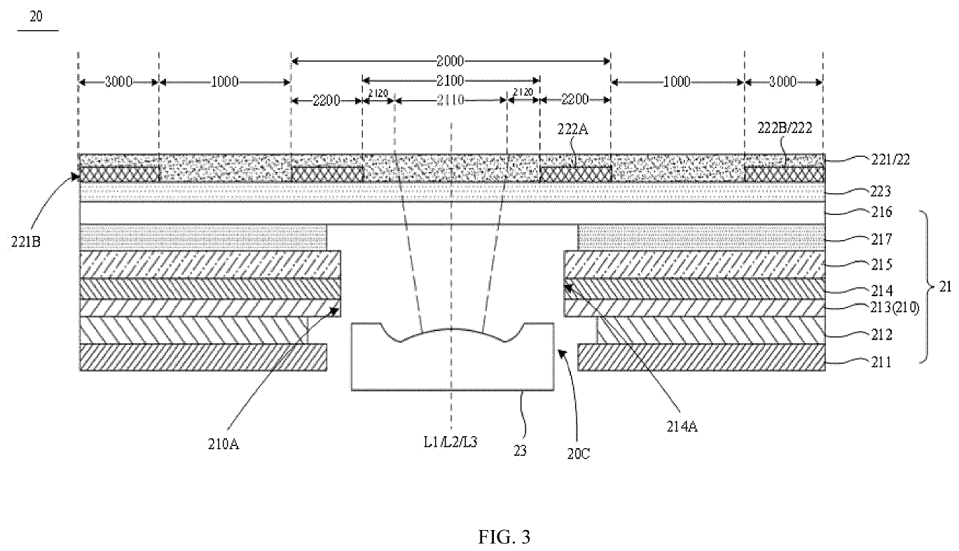

Combining FIG. 2 and FIG. 3, FIG. 2 is a top view of a display device provided by embodiments of the present application; and FIG. 3 is a cross-section diagram of a first structure of the display device at A-A′ in FIG. 2.

This embodiment provides a display device 20, which includes a bending part 20A and a non-bending part 20B adjacent to the bending part 20A; where, this embodiment uses FIG. 2 as a cross-section diagram while the display device 20 is in a first state, and takes the first state of the display device 20 is a flattening state as an example to illustrate the solutions of the present application.

The display device 20 includes a display module 21 and a cover plate 22 disposed on a side of a light-emitting direction of the display module 21; the display module 21 includes a supporting film layer 211, a buffer layer 212, a back plate 213, a display panel 214, a polarizer 215, and a flexible substrate 216 together in a laminated arrangement; and the cover plate 22 is located on a side of the flexible substrate 216 away from the display panel 214.

Furthermore, the flexible substrate 216 is pasted with the polarizer 215 through a first adhesive layer 217, and the buffer layer 212 and the supporting film layer 211 may be pasted through a second adhesive layer, where a material of the supporting film layer 211 includes but is not limited to stainless steel (SUS), a material of the flexible substrate 216 includes but is not limited to one of colorless and transparent polyimide (CPI), polyethylene terephthalate (PET) or ultra-thin glass (UTG), and the display panel 214 may be an organic light-emitting diode display panel 214 (OLED) or a light-emitting diode display panel 214 (LED), which is not specifically limited in this embodiment.

In an embodiment, the display module 21 also includes a heat dissipation film layer, which is located between the buffer layer 212 and the supporting film layer 211, and a material of the heat dissipation film layer includes, but is not limited to, foam rubber.

In an embodiment, the display device 20 includes a functional addition area 2000 and a display area 1000 located in a periphery of the functional addition area 2000, the functional addition area 2000 includes a functional area 2100 and a first transition area 2200 located between the display area 1000 and the functional area 2100, and the first transition area 2200 is disposed around the functional area 2100. The display device 20 includes a camera assembly 23, and the camera assembly 23 is disposed corresponding to the functional area 2100; where the camera assembly 23 includes, but is not limited to, a camera.

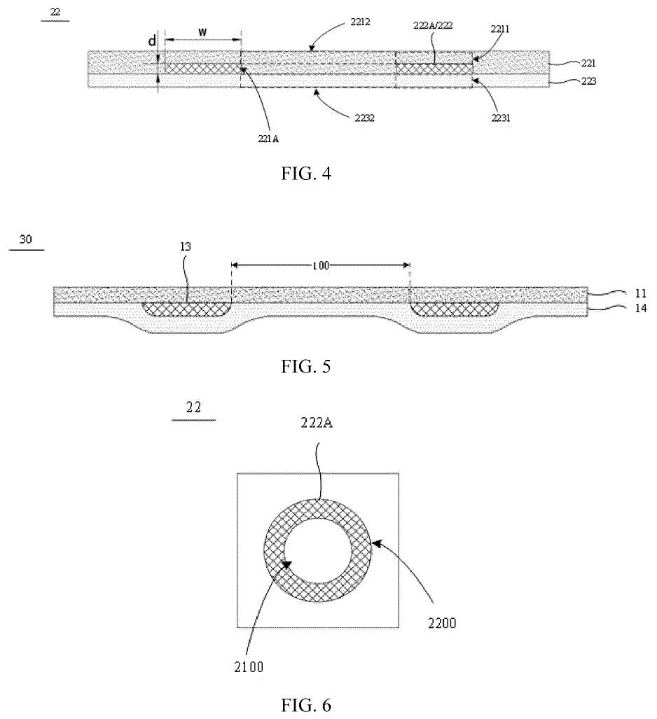

Combining FIG. 2 and FIG. 4, FIG. 4 is a cross-section diagram of a cover plate provided by embodiments of the present application. The cover plate 22 includes a cover plate main body 221, and the cover plate main body 221 is provided with a first groove 221A. The first groove 221A is located in the first transition area 2200 and surrounds the functional area 2100. The cover plate 22 further includes a light-shielding layer 222, which is filled in the first groove 221 A; where a material of the light-shielding layer 222 includes but is not limited to ink, and the ink may be black ink.

It should be noted that in this embodiment, the light-shielding layer is filled in the first groove of the cover plate main body, and a thickness of the light-shielding layer is less than or equal to a depth of the first groove, which avoids an influence of the thickness of the light-shielding layer on a thickness of the cover plate main body, avoids a thickness difference of the cover plate main body at different positions of the functional addition area, and then prevents an optical path difference of light passing through different positions of the cover plate, thereby ensuring an optical imaging quality of the camera.

Furthermore, combining FIG. 1 and FIG. 4, in an embodiment, the cover plate main body 221 includes a first main body part 2211 and a second main body part 2212. The first main body part 2211 is disposed in the first transition area 2200, and the second main body part 2212 is disposed in the functional area 2100; where, a side of the first main body part 2211 away from the display module 21 is flush with a side of the second main body 2212 away from the display module 21.

The light-shielding layer 222 includes a first light-shielding part 222A. The first light-shielding part 222A is filled in the first groove 221A. The first light-shielding part 222A is an annular structure. A sum of a thickness of the first light-shielding part 222A and a thickness of the first main part 2211 is less than or equal to a thickness of the second main body part 2212. In an embodiment, the thickness of the first light-shielding part 222A is equal to the depth of the first groove 221A, a width of the first light-shielding part 222A is equal to a width of the first groove 221A, and a depth d of the first groove 221A is greater than or equal to 1 micron and less than or equal to half of a thickness of the cover plate main body 221. A width w of the first groove 221A is greater than or equal to 0.3 mm and less than or equal to 1 mm. The sum of the thickness of the first light-shielding part 222A and the thickness of the first main part 2211 is equal to the thickness of the second main body part 2212, so that a side of the first main part 2211 away from the display module 21 is flush with a side of the second main body part 2212 away from the display module 21, which reduces a segment difference generated on the cover plate main body 221 and improves a flatness of the cover plate main body 221. Thus, an optical path difference of light passing through different positions of the cover plate 22 in the functional addition area 2000 is eliminated, and an imaging quality of an under-screen camera is improved.

It should be noted that the thickness of the first light-shielding part 222A is equal to the depth of the first groove 221A, and a width of the light-shielding layer 222 is equal to the width of the first groove 221A, which is for illustration only. In another embodiment, a thickness of the light-shielding layer 222 is less than the depth of the first groove 221A. In addition, an absolute value of a difference between the thickness of the light-shielding layer 222 and the depth of the first groove 221A is less than or equal to 2 microns, and the thickness of the light-shielding layer 222 is not specifically limited in this embodiment.

In an embodiment, the cover plate 22 further includes an adhesive layer 223, which is disposed between the cover plate main body 221 and the display module 21, and the first groove 221A is located on a side of the cover plate main body 221 close to the adhesive layer 223. The adhesive layer 223 includes a first adhesive part 2231 disposed in the first transition area 2200 and a second adhesive part 2232 disposed in the functional addition area 2000. A side of the first adhesive part 2231 away from the cover plate main body 221 is flush with a side of the second adhesive part 2232 away from the cover plate main body 221.

An orthogonal projection of the adhesive layer 223 on the light-shielding layer 222 covers the light-shielding layer 222. The cover plate main body 221 is bonded to the display module 21 through the adhesive layer 223. A material of the adhesive layer 223 includes but is not limited to optical adhesive. A material of the optical adhesive includes but is not limited to one of solid optical adhesive or liquid optical adhesive. While the optical adhesive is a solid optical adhesive, the solid optical adhesive may be OCA optical adhesive.

Furthermore, combining FIG. 2, FIG. 4 and FIG. 5, FIG. 5 is a structure diagram of a traditional packaging structure. It should be noted that a traditional packaging structure 30 shown in FIG. 5 may be used to package the display device of an under-screen camera. In the packaging structure 30, the ink layer 13 is located between the cover plate 11 and the adhesive 14, and an orthogonal projection of the adhesive 14 on the cover plate 11 covers an orthogonal projection of the ink layer 13 on the cover plate 11. In addition, the ink layer 13 has a certain thickness, leading to a thickness of the adhesive 14 at different positions in a light transmitting area 100 is inconsistent, and an optical path difference of light entering a camera hole at different positions in the light transmitting area 100 is inconsistent, resulting in an optical path distortion of an incident light entering the camera, which has a deteriorating effect on an imaging of the camera.

It should be noted that in this embodiment, the first light-shielding part 222A is filled in the first groove 221A, and the thickness of the first light-shielding layer 222A is less than or equal to the depth of the first groove 221A. The side of the first viscose part 2231 away from the cover plate main body 221 is flush with the side of the second viscose part 2232 away from the cover plate main body 221, so as to avoid the difference of the thickness of the adhesive layer 223 at different positions in the functional addition area 2000, and then eliminate the optical path difference of the light passing through the different positions of the adhesive layer 223 in the functional addition area 2000. Thus the imaging quality of the under-screen camera is improved.

In an embodiment, the display device 20 further includes a non-display area 3000, the non-display area 3000 is located at a side of the display area 1000 away from the functional addition area 2000, and the non-display area 3000 is disposed around the display area 1000. A second groove 221B is opened on the cover plate main body 221, and the second groove 221B is located in the non-display area 3000 and surrounds the display area 1000. The light-shielding layer 222 includes a second light-shielding part 222B, the second light-shielding part 222B is filled in the second groove 221B, and an absolute value of a difference between a thickness of the second light-shielding part 222B and a depth of the first groove 221A is less than or equal to 2 microns. This embodiment does not specifically limit the thickness of the second light-shielding part 222B.

It should be noted, in this embodiment, the second groove 221B is disposed on the cover plate main body 221, and the second light-shielding part 222B is filled in the second groove 221B, so that a flatness of a side of the cover plate main body 221 close to the display panel 214 is effectively guaranteed. In addition, the second light-shielding part 222B is filled in the second groove 221B, which would not increase the thickness of the cover plate main body 221 relative to the display area 1000. While connecting the cover plate main body 221 and the flexible substrate 216 through the adhesive layer 223, a phenomenon that the cover plate main body 221 separates from the flexible substrate 216 due to an uneven thickness of the cover plate main body 221 may be avoided.

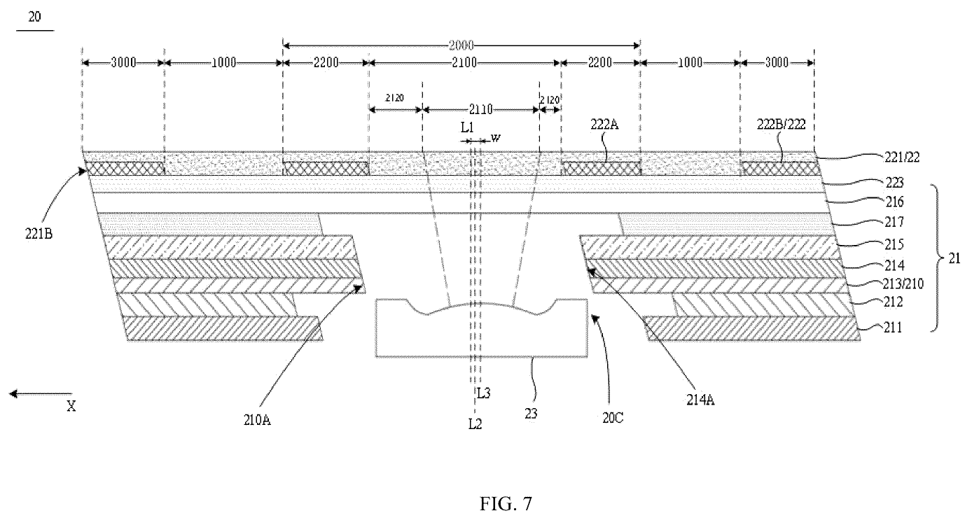

In an embodiment, combining FIG. 2, FIG. 6 and FIG. 7, FIG. 6 is a cross-section top view of a first structure of the cover plate provided by embodiments of the present application, and FIG. 7 is a cross-section diagram of a second structure of the display device at A-A′ in FIG. 2.

It should be noted that in the existing technology, an opening design is usually carried out on the display panel, and a front camera is placed under an opening to realize a photography function of a display product. Due to a dislocation between film layers during folding processes of the display product, a design of the front camera in a screen would cause problems such as interference between a camera and the screen. This embodiment uses FIG. 4 and FIG. 7 as examples to illustrate the solutions of the present application, FIG. 4 is a cross-section top view of the cover plate while the display device is in a first state, and FIG. 7 is a cross-section diagram while the display device is in a second state and the second state of the display device is a bending state.

In this embodiment, the display device 20 includes a bending part 20A and a non-bending part 20B adjacent to the bending part 20A; and the functional addition area 2000 is located at the non-bending part 20B; where this embodiment takes the first state of the display device 20 is a flattening state, and the second state of the display device 20 is the bending state as an example to illustrate the solutions of the present application.

The display panel 214 is provided with a first through-hole 214A, which is disposed around the functional area 2100, and an aperture of the first through-hole 214A is larger than a width of the functional area 2100; where while the display device 20 is in the first state, the first through-hole 214A is coaxially disposed with the functional area 2100; and while the display device 20 is in the second state, a central axis L1 of the first through-hole 214A and a central axis L2 of the functional area 2100 are parallel and disposed at intervals.

In addition, the functional area 2100 includes an imaging area 2110 corresponding to a field angle of a camera assembly 23, and a second transition area 2120 located between the imaging area 2110 and the first transition area 2200. When the display device 20 is in the second state, a side of the display panel 214 close to the first through-hole 214A is located at a side of the second transition area 2120 away from the imaging area 2110; that is, the display panel 214 is not located in the imaging area 2110. When the display device 20 is in the second state, in a first direction X, a distance between one side wall of the first light-shielding part 222A and a straight line of the central axis L3 of the camera assembly 23 is not equal to a distance between another side wall of the first light-shielding part 222A and the straight line of the central axis L3 of the camera assembly 23, which effectively prevents an interference between the camera and the display panel 214.

It should be noted that the display device described in this embodiment may be applied to inner folding display devices or outer folding display devices. The difference between the inner folding display devices and the outer folding display devices is that displacement direction of multi-film structure is opposite. Furthermore, in the inner folding display devices, a moving direction of the multi-film structure in the display device is a direction of a bending part pointing to a non-bending part. In the outer folding display devices, a moving direction of the multi-film structure in the display device is a direction from the non-bending part pointing to the bending part.

The solutions of the present application are illustrated by taking the display device as an example. The display device is an internal folding display device, a moving direction of the multi-film structure in the display device 20 is the first direction X, and the first direction X is a direction of the moving direction of the multi-film structure in the display device and is a direction of the bending part pointing to the non-bending part.

In an embodiment, the display device 20 further includes a functional layer 210, which is located on a side of the display panel 214 away from the cover plate 22. The functional layer 210 is provided with a second through-hole 210A, and an aperture of the second through-hole 210A is equal to an aperture of the first through-hole 214A; where the functional layer 210 may be any film layer in a back plate 213, a buffer layer 212 or a supporting film layer 211. This embodiment takes the functional layer 210 being the back plate 213 as an example to illustrate the solutions of the present application.

In this embodiment, while the display device 20 is in the first state, th second through-hole 210A is disposed around the functional area 2100. While the display device 20 is in the second state, a side of the functional layer 210 close to the second through-hole 210A is located in the functional addition area 2000, and the central axis L1 of the first through-hole 214A is located at a side of the central axis L2 of the second through-hole 210A away from the central axis L3 of a camera assembly 23. While the display device 20 is in the first state, the first through-hole 214A, the second through-hole 210A and the camera assembly 23 are coaxially disposed. While the display device 20 is in the second state, a preset dislocation distance w is disposed between the central axis L1 of the first through-hole 214A and the central axis L3 of the camera assembly 23. Furthermore, the central axis L1 of the first through-hole 214A is offset by the preset dislocation distance w along the first direction X relative to the central axis L3 of the camera assembly 23. A width of the second transition area 2120 is greater than the preset dislocation distance w, and the width of the second transition area 2120 is greater than or equal to 150 microns, and less than or equal to 800 microns. A hole-like structure has a first aperture and a second aperture, and the first aperture is different from the second aperture. The camera is nested in the hole-like structure.

An orthogonal projection of the functional layer 210 close to a side of the second through-hole 210A on the light-shielding layer 222 is located in the light-shielding layer 222, so that while the display device 20 is in the second state, a dislocation movement of each functional layer form a coverage of the camera assembly 23, thereby improving the imaging effect of the camera assembly 23 and the stability of the display device 20.

The display device 20 includes a camera hole 20C, and the camera hole 20C is disposed corresponding to the functional area 2100. The camera hole 20C passes through the first adhesive layer 217, the polarizer 215, the display panel 214, the back plate 213, the buffer layer 212 and the supporting film 211 in turn. The camera hole 20C includes a first through-hole 214A and a second through-hole 210A.

It should be noted that due to different bending radii of each film layer in the display module 21 and different materials of each film layer, while the display device 20 is bent from the flattening state to the folding state, each film layer of the display module 21 produces a dislocation amount at the camera hole 20C, that is, a negative dislocation, and differences exists between generated dislocation amounts. This embodiment uses a preset dislocation distance w between the central axis L1 of the first hole 214A and the central axis L3 of the camera assembly 23 as an example to illustrate the solutions of the present application. The preset dislocation distance is selected based on an actual production situation, which is not limit in this embodiment.

In an embodiment, the functional area 2100 is a hole-like structure. While the display device 20 is in the first state, a shape of a cross section of the hole-like structure may be a symmetrical figure such as a circle or a rectangle. While the display device 20 is in the second state, the hole-like structure has the first aperture and the second aperture, and the first aperture is different from the second aperture. An orthogonal projection of the hole-like structure on the display device 20 is located in the second through-hole 210A, and the orthogonal projection of the hole-like structure on the display device 20 is located in an inner ring of the first light-shielding layer 222A, thereby preventing problems such as interference between the camera and the functional layer 210, and between the camera and the first light-shielding layer 222A.

In an embodiment, in the first direction X, a distance between a side wall of the inner ring of the first light-shielding part 222A and a side of the functional layer 210 close to the second through-hole 210A is greater than the preset dislocation distance w, which may effectively avoid an edge exposure of the functional layer 210 in the camera hole 20C while the display device 20 is bent, affecting overall aesthetics of the display device 20.

This embodiment provides a mobile terminal. The mobile terminal includes a terminal body and the display device described in any of the above embodiments. The terminal body is integrated with the display device.

It should be noted that the display device has been described in detail in the above embodiment, and is not repeated here.

In specific applications, the mobile terminal may be a display screen for smart phones, tablets, laptops, smart bracelets, smart watches, smart glasses, smart helmets, desktop computers, smart TVs or digital cameras, and may even be applied to electronic devices with flexible display screens.

In summary, although the present application has been disclosed as above embodiments, the above embodiments are not used to limit the present application. Those skilled in the art may make various changes and modifications without deviating from the nature and scope of the present application. Therefore, the scope of protection of the present application is subject to the scope defined by the claims.

What is claimed is:

1. A display device, comprising a functional addition area and a display area located on a periphery of the functional addition area, wherein the functional addition area comprises a functional area and a first transition area located between the display area and the functional area; and further comprising:
a display panel; and
a cover plate, disposed on the display panel, wherein the cover plate comprises a cover plate main body, the cover plate main body is provided with a first groove, and the first groove is located in the first transition area and surrounds the functional area;
wherein the cover plate further comprises a light-shielding layer, and the light-shielding layer is filled in the first groove.

2. The display device of claim 1, wherein the display device further comprises a bending part and a non-bending part adjacent to the bending part; and
the display panel is provided with a first through-hole, disposed around the functional area, and an aperture of the first through-hole is larger than a width of the functional area; wherein
while the display device is in a first state, the first through-hole is coaxially disposed with the functional area; and
while the display device is in a second state, a central axis of the first through-hole and a central axis of the functional area are parallel and disposed at intervals.

3. The display device of claim 2, further comprising a camera assembly, wherein the camera assembly is disposed corresponding to the functional area; and
the functional area comprises an imaging area corresponding to a field angle of the camera assembly, and a second transition area located between the imaging area and the first transition area;
wherein while the display device is in the second state, a side of the display panel close to the first through-hole is located at a side of the second transition area away from the imaging area.

4. The display device of claim 3, wherein the display device further comprises a functional layer, located on a side of the display panel away from the cover plate, the functional layer is provided with a second through-hole, and an aperture of the second through-hole is equal to the aperture of the first through-hole;
while the display device is in the first state, the second through-hole is disposed around the functional area; and
while the display device is in the second state, a side of the functional layer close to the second through-hole is located in the functional addition area, and the central axis of the first through-hole is located at a side of a central axis of the second through-hole away from a central axis of a camera assembly.

5. The display device of claim 4, wherein while the display device is in the first state, the first through-hole and the camera assembly are coaxially disposed; and
while the display device is in the second state, there is a preset dislocation distance disposed between the central axis of the first through-hole and the central axis of the camera assembly.

6. The display device of claim 5, wherein the central axis of the first through-hole is offset by the preset dislocation distance along the first direction relative to the central axis of the camera assembly, and a width of a second transition area is greater than the preset dislocation distance.

7. The display device of claim 6, wherein the width of the second transition area is greater than or equal to 150 microns, and less than or equal to 800 microns.

8. The display device of claim 5, wherein the functional area is a hole-like structure, while the display device is in the first state, a shape of a cross section of the hole-like structure is a circle; while the display device is in the second state, the hole-like structure has a first aperture and a second aperture, and the first aperture is different from the second aperture.

9. The display device of claim 8, wherein the light-shielding layer comprises a first light-shielding part, the first light-shielding part is filled in the first groove, and the first light-shielding part is an annular structure;
wherein while the display device is in the second state, in a first direction, a distance between one side wall of the first light-shielding part and a straight line of the central axis of the camera assembly is not equal to a distance between another side wall of the first light-shielding part and the straight line of the central axis of the camera assembly.

10. The display device of claim 9, wherein a distance between a side wall of an inner ring of the first light-shielding part and a side of the functional layer close to the second through-hole is greater than the preset dislocation distance.

11. The display device of claim 9, wherein the cover plate main body comprises a first main body part and a second main body part, the first main body part is disposed in the first transition area, and the second main body part is disposed in the functional are, and a side of the first main body part away from a display module is flush with a side of the second main body away from the display module;
wherein a sum of a thickness of the first light-shielding part and a thickness of the first main part is less than or equal to a thickness of the second main body part.

12. The display device of claim 9, wherein the display device further comprises a non-display area, the non-display area is located at a side of the display area away from the functional addition area, and the non-display area is disposed around the display area;
the cover plate main body is provided with a second groove, and the second groove is located in the non-display area and surrounds the display area; and
the light-shielding layer comprises a second light-shielding part, the second light-shielding part is filled in the second groove, and a thickness of the second light-shielding part is less than or equal to a depth of the second groove.

13. The display device of claim 1, wherein the display device further comprises a display module, the display module comprises a supporting film layer, a buffer layer, a back plate, the display panel, a polarizer, and a flexible substrate in a laminated arrangement; wherein the cover plate is located on a side of the flexible substrate away from the display panel.

14. The display device of claim 13, wherein the cover plate further comprises an adhesive layer disposed between the cover plate main body and the display module, and the first groove is located on a side of the cover plate main body close to the adhesive layer;
wherein the adhesive layer comprises a first adhesive part disposed in the first transition area and a second adhesive part disposed in the functional addition area, and a side of the first adhesive part away from the cover plate main body is flush with a side of the second adhesive part away from the cover plate main body.

15. The display device of claim 14, wherein an orthogonal projection of the adhesive layer on the light-shielding layer covers the light-shielding layer.

16. The display device of claim 15, wherein a material of the light-shielding layer is black ink, and a material of the adhesive layer is optical adhesive.

17. A mobile terminal, comprising a terminal main body and a display device, wherein the terminal main body is integrated with the display device, and the display device comprises a functional addition area and a display area located on a periphery of the functional addition area, wherein the functional addition area comprises a functional area and a first transition area located between the display area and the functional area; and further comprising:
a display panel; and
a cover plate, disposed on the display panel, wherein the cover plate comprises a cover plate main body, the cover plate main body is provided with a first groove, and the first groove is located in the first transition area and surrounds the functional area;
wherein the cover plate further comprises a light-shielding layer, and the light-shielding layer is filled in the first groove.

18. The mobile terminal of claim 17, wherein the display device comprises a bending part and a non-bending part adjacent to the bending part; and
the display panel is provided with a first through-hole, disposed around the functional area, and an aperture of the first through-hole is larger than a width of the functional area; wherein
while the display device is in a first state, the first through-hole is coaxially disposed with the functional area; and
while the display device is in a second state, a central axis of the first through-hole and a central axis of the functional area are parallel and disposed at intervals.

19. The mobile terminal of claim 18, wherein the display device further comprises a camera assembly, and the camera assembly is disposed corresponding to the functional area; and
the functional area comprises an imaging area corresponding to a field angle of the camera assembly, and a second transition area located between the imaging area and the first transition area;
wherein while the display device is in the second state, a side of the display panel close to the first through-hole is located at a side of the second transition area away from the imaging area.

20. The mobile terminal of claim 19, wherein the display device further comprises a functional layer located on a side of the display panel away from the cover plate, the functional layer is provided with a second through-hole, and an aperture of the second through-hole is equal to an aperture of the first through-hole; wherein
while the display device is in the first state, the second through-hole is disposed around the functional area; and
while the display device is in the second state, a side of the functional layer close to the second through-hole is located in a functional addition area, and the central axis of the first through-hole is located at a side of a central axis of the second through-hole away from a central axis of the camera assembly.
